(19) United States
(12) Patent Application Publication
(10) Pub. No.: US 2025/0273617 A1
(43) Pub. Date: Aug. 28, 2025

(54) POWER MODULE PACKAGING STRUCTURE BASED ON LIQUID METAL

(71) Applicant: CAMBRIDGE INTEGRATION LTD, Cambridge (GB)

(72) Inventors: Wei MU, Nanjing (CN); Teng LONG, Beijing (CN); Ameer Hussein Abd JANABI, Cambridge (GB)

(73) Assignee: CAMBRIDGE INTEGRATION LTD, Cambridge (GB)

(21) Appl. No.: 19/061,297

(22) Filed: Feb. 24, 2025

(30) Foreign Application Priority Data
Feb. 23, 2024 (CN) 202410199603.2
Feb. 27, 2024 (CN) 202410212041.0

(51) Int. Cl. H01L 23/00; H01L 23/13; H01L 23/31; H01L 23/498

(52) U.S. Cl. CPC H01L 24/29; H01L 23/3185; H01L 23/49833; H01L 24/32; H01L 24/33; H01L 23/13; H01L 23/4985; H01L 2224/29105; H01L 2224/29109; H01L 2224/29111; H01L 2224/29139; H01L 2224/32225; H01L 2224/33181

(57) ABSTRACT

A power module packaging structure based on liquid metal, including an upper printed circuit board or an upper cermet substrate, a power semiconductor chip and a lower cermet substrate, wherein a lower surface copper layer of the circuit board is connected with the chip through a soldering layer, a groove is formed in an upper copper layer of the lower cermet substrate through etching, the surface of the upper copper layer of the lower cermet substrate is subjected to silver plating, liquid metal is filled in the groove, and the chip is embedded into the liquid metal to realize electrical connection between the upper surface of the lower cermet substrate and the lower surface of the chip; an insulating sealing ring is arranged on the circuit board around the chip; and the liquid metal absorbs the lower cermet substrate and the upper printed circuit board together through surface tension.

### TECHNICAL FIELD

The present invention relates to a power module packaging structure based on liquid metal.

### BACKGROUND

In the prior art, a power electronic packaging structure is generally faced with a thermo-mechanical stress problem due to mismatch of a coefficient of thermal expansion (CTE) of a material. Since a silicon carbide (SiC) material has a large difference in the coefficient of thermal expansion of a material from conventional packaging materials (e.g., copper, aluminum, ceramic, etc.) and the SiC material has a high Young modulus, this problem is particularly acute when a SiC power module is packaged, especially in high-power and high-temperature operating environment. Especially, in the high-temperature operating environment, the thermo-mechanical stress in the existing package structures increases significantly. Such stress can lead to stripping or cracking at a packaging interface, thereby reducing the reliability and lifetime of the device. Conventional solutions include using soft materials as buffer layers or changing the package design to accommodate thermal expansion, but these approaches tend to affect the electrical and thermal performance of the packaging.

In the prior art, packaging methods typically rely on rigid soldering materials to connect a chip and a substrate. These soldering materials are susceptible to fatigue and creep under the influence of thermal cycling, thereby reducing the reliability and lifetime of the module. In addition, the rigid connection may also lead to mechanical damage of the chip, especially in the case of mechanical shocks or drastic changes in temperature, which is even more pronounced, especially for thin or large-area chips. Furthermore, since the silicon carbide power module has high requirements on the thermal performance of the packaging, the buffer material in the prior art may not satisfy the requirements of low thermal resistance and high mechanical flexibility at the same time.

### SUMMARY

The technical problems to be solved by the present invention are as follows: a power module packaging structure based on liquid metal is provided to reduce thermo-mechanical stress and improve device reliability.

In order to solve the technical problems, the technical solution used in the present invention is: a power module packaging structure based on liquid metal, comprising an upper printed circuit board or an upper cermet substrate, a power semiconductor chip and a lower cermet substrate, wherein a lower surface copper layer of the upper printed circuit board is connected with the power semiconductor chip through a soldering layer, a groove is formed in an upper copper layer of the lower cermet substrate through etching, the surface of the upper copper layer of the lower cermet substrate is subjected to silver plating, liquid metal is filled in the groove, and the power semiconductor chip is embedded into the liquid metal in the groove so as to realize electrical connection between the upper surface of the lower cermet substrate and the lower surface of the power semiconductor chip;
an insulating sealing ring is arranged on the upper printed circuit board around the power semiconductor chip to prevent the liquid metal from entering between the power semiconductor chip and the upper printed circuit board to cause short circuit; the liquid metal absorbs the lower cermet substrate and the upper printed circuit board together through surface tension; and
a grid electrode and a source electrode of the lower surface copper layer of the upper printed circuit board are connected with a grid electrode and a source electrode of the power semiconductor chip through the soldering layer, and a drain electrode copper layer on the lower surface of the power semiconductor chip is connected with the upper surface copper layer of the cermet substrate through the liquid metal; the lower surface copper layer of the upper printed circuit board is connected to the corresponding copper layer on the flexible upper surface through a through hole so as to realize electrical connection between the copper layers of the upper surface and the lower surface; and an upper surface copper layer of the upper printed circuit board is used as a power terminal of the packaging structure.

As a preferred solution, the insulating sealing ring is made of epoxy resin, silicon rubber, polyamide, polyimide or resin.

As a preferred solution, the power semiconductor chip is a silicon carbide power semiconductor chip or a gallium nitride power semiconductor chip or a silicon power semiconductor chip or a gallium oxide power semiconductor chip or a diamond power semiconductor chip.

As a preferred solution, the liquid metal is gallium indium silver alloy or gallium indium tin alloy.

As a preferred solution, the lower cermet substrate is of a copper-ceramic-copper three-layer structure.

As a preferred solution, the upper printed circuit board is a common printed circuit board or a flexible printed circuit board.

The present invention has the following beneficial effects:
1. The overall thermo-mechanical stress is greatly reduced: the technology realizes the electrical connection inside the packaging through the liquid metal, decouples the difference of thermal strain among the chip, PCB and cermet substrate by utilizing the fluid characteristic of the liquid metal during working, and greatly reduces the thermal stress of the whole packaging structure.
2. The shear stress at the interface is significantly reduced: the packaging based on a traditional rigid interface connection mode (soldering/sintering) is changed into a flexible connection based on the liquid metal, thereby significantly reducing the shearing stress caused by mismatching of a coefficient of thermal expansion on the interface of two different materials and reducing the possibility of peeling of the upper printed circuit board.
3. The module reliability is improved: the technology eliminates the thermo-mechanical stress of a connecting layer by using connection by the liquid metal instead of rigid connection (such as soldering and nano silver sintering). This design maintains excellent thermal and electrical performances and also significantly reduces thermal stress of the silicon carbide power module, thereby improving reliability of long-term operation of the module.
4. The electrical and thermal conductive performances are ensured: the packaging structure based on liquid metal in the structure can provide electric conduction and thermal conduction performances similar to those of traditional soldering. Besides, since an insulating sealing protective layer is used on the periphery of the chip, the pressure resistance of the device cannot be influenced.
5. The process flow of module manufacturing is simplified: due to application of the liquid metal with high thermal and electrical conductivity in power electronics, the technology provides the possibility of fluid interconnection at room temperature while avoiding the high temperature and pressure environment of conventional soldering or sintering processes, and thus has little impact on the semiconductor device itself.
6. The cost is low and maintenance and material recycling are facilitated: the cost of the liquid metal used in the packaging structure based on liquid metal is significantly lower than that of a sintered silver paste and the use of a reflow soldering machine or a sintering furnace is not needed. Meanwhile, as the liquid metal is used as the interconnection material, the lossless separation of each part of the packaging structure can be realized, and the maintenance, replacement and material recycling are facilitated.

### BRIEF DESCRIPTION OF THE DRAWINGS

FIG. 1 is a schematic perspective view of the utility model;

FIG. 2 is a schematic section view of the utility model;

FIG. 3(a) shows the thermo-mechanical stress of a conventional soldering tin-based packaging structure;

FIG. 3(b) shows the thermo-mechanical stress of the packaging based on liquid metal;

FIG. 4(a) shows the volume thermal strain of the conventional soldering tin-based packaging structure;

FIG. 4(b) shows the volume thermal strain of the packaging based on liquid metal;

FIG. 5(a) shows the shear stress at top copper of the conventional soldering tin-based packaging structure;

FIG. 5(b) shows the shear stress at top copper of the packaging based on liquid metal;

FIG. 6(a) shows the shear stress of a bottom copper layer of a flexible PCB of the conventional soldering tin-based packaging structure;

FIG. 6(b) shows the shear stress of a bottom copper layer of a flexible PCB of the packaging based on liquid metal;

FIG. 7 shows a comparison of chip upper surface-to-ambient thermal resistance.

FIG. 8 shows a comparison of the output characteristics of the conventional soldering tin-based packaging and the packaging based on liquid metal in the example at different pressures (Vgs=18 V); and

FIG. 9 shows a measurement result of a leakage current of the packaging based on liquid metal (Vgs=0 V),

in the figure: 1. upper printed circuit board, 2. power semiconductor chip, 3. lower cermet substrate, 4. soldering layer, 5. groove, 6. liquid metal and 7. insulating sealing ring.

### DETAILED DESCRIPTION

The specific implementations of the present invention are described in detail below with reference to the accompanying drawings.

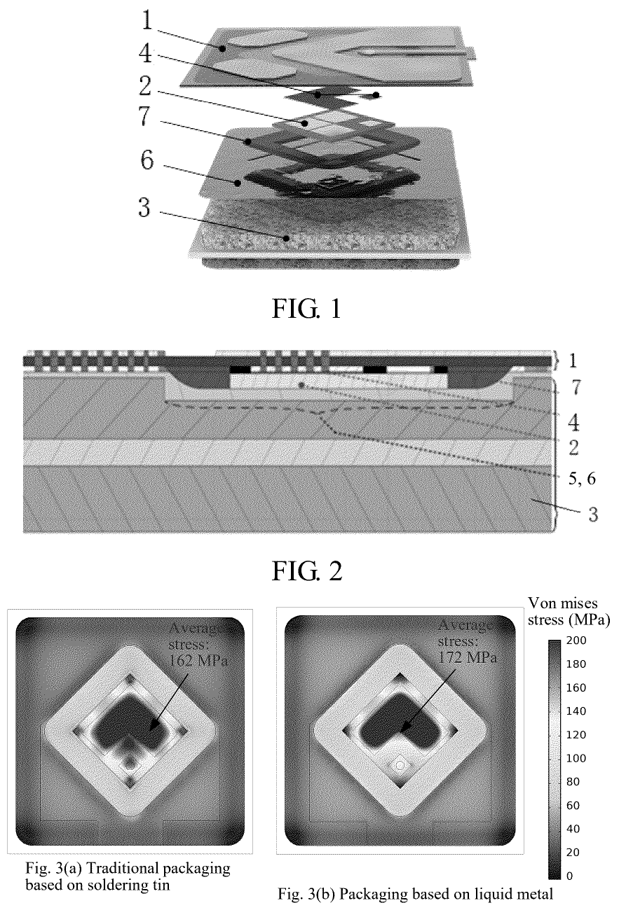

As shown in FIGS. 1-2, a power module packaging structure based on liquid metal comprises an upper printed circuit board 1, a power semiconductor chip 2 and a lower cermet substrate 3, wherein a lower surface copper layer of the flexible upper printed circuit board 1 is connected with the power semiconductor chip 2 through a soldering layer 4, a groove 5 is formed in an upper copper layer of the lower cermet substrate 3 through etching, the surface of the upper copper layer of the lower cermet substrate 3 is subjected to silver plating, and liquid metal 6, namely gallium indium silver alloy, is filled in the groove 5. Besides, the power semiconductor chip 2 is embedded into the liquid metal 6 in the groove 5 so as to realize electrical connection between the upper surface of the lower cermet substrate 3 and the lower surface of the power semiconductor chip 2.

An epoxy resin insulating sealing ring 7 is arranged on the flexible upper printed circuit board 1 around the power semiconductor chip 2 to prevent the liquid metal 6 from entering between the power semiconductor chip 2 and the flexible upper printed circuit board 1 to cause short circuit; and the liquid metal 6 absorbs the lower cermet substrate 3 and the upper printed circuit board 1 together through surface tension.

A grid electrode and a source electrode of the lower surface copper layer of the flexible upper printed circuit board 1 are connected with a grid electrode and a source electrode of the power semiconductor chip 2 through the soldering layer 4, and a drain electrode copper layer on the lower surface of the power semiconductor chip 2 is connected with the upper surface copper layer of the cermet substrate through the liquid metal 6; the lower surface copper layer of the flexible upper printed circuit board 1 is connected to the corresponding copper layer on the flexible upper surface through a through hole so as to realize electrical connection between the copper layers of the upper surface and the lower surface; and an upper surface copper layer of the flexible upper printed circuit board 1 is used as a power terminal of the packaging structure.

In the present example, the liquid metal material consisting of silver, indium and gallium is used. Compared with an SAC 305 solder, the liquid metal material has competitive thermal and electrical performances (thermal conductivity of 75 W/(mK) and electrical conductivity is 5×10⁶ S/m). In addition, the gallium indium silver alloy is a non-toxic material and has the relatively low melting point of 8° C., thereby becoming a feasible interconnection material at room temperature.

A drain electrode using SiC MOSFET (SCT116N120G3DXAG, 1,200 V, 130 A) is Ti/Ni/Ag and shows chemical stability when contacting with gallium in the gallium indium silver alloy liquid metal. The cermet substrate is subjected to silver plating so as to ensure good adhesion with the gallium indium silver alloy liquid metal. Therefore, the liquid metal can be better adhered to the surfaces of the cermet substrate and the chip metal, and the thermal resistance and electric resistance at the interface are reduced.

TABLE 1

| Parameter | Value | |
|---|---|---|
| Cermet substrate size (length) × | 15 mm × 15 mm × 1.92 mm | |
| (width) × (thickness) | | |
| Thickness of copper layer of | 0.8 | mm |
| cermet substrate | | |
| Thickness of silicon nitride ceramic | 0.32 | mm |
| layer of cermet substrate | | |
| Chip size (length) × | 5.1 mm × 5.1 mm × 0.18 mm | |
| (width) × (thickness) | | |
| Groove size (length) × (width) | 7 mm × 7 mm | |
| Depth of groove | 210 | μm |
| Silver-plating thickness of surface | 450 | nm |
| layer of cermet substrate | | |

Since the liquid metal has a high surface tension with a coefficient y greater than 500 mN/m, the specification of the packaging provided in the example is shown in Table 1 above. The total circumference L of the contact interface between the cermet substrate and the liquid metal-covered flexible printed circuit board is 54.3 mm. The surface tension is calculated and the minimum force F=2≡L required to separate the two surfaces is 54.3 mN, indicating that the surface tension of the liquid metal can support the total weight of the packaging (28.6 mN). In addition, the extremely high surface tension ensures that the liquid metal stays between the interfaces without random flow.

The flexible printed circuit board consists of a polyimide core layer of 0.29 mm thin with two 2 ounce copper layers on both sides. By connecting a source electrode and a grid electrode, a solder is used between the chip and the flexible printed circuit board, thereby achieving precise connection of the top side of the chip and keeping the chip floating around the center of a cavity. Unlike chip mounting between the chip and the cermet substrate, since the flexible printed circuit board has a low Young modulus and a thin thickness, a soldering layer between the flexible printed circuit board and the chip does not bear high thermal stress. In addition, the thin flexible printed circuit board structure can also realize a smaller power loop and effectively reduce parasitic inductance and electrical resistance.

A finite element analysis is used to evaluate and compare the thermo-mechanical stress of the packaging based on liquid metal and the packaging based on a solder:
for thermal modeling, a loss of 100 W of the packaging is set as a heat source. The bottom side of the cermet substrate is set to a heat transfer coefficient of 7,500 W/(m²K), representing the cooling capacity provided by a liquid cooling plate in the experiment. All other boundaries are adiabatic. During mechanical modeling, a coulomb friction model is used for a contact interface between the flexible printed circuit board and the cermet substrate with a friction coefficient of 0.5. For the packaging based on liquid metal, the top surface of the flexible printed circuit board is subjected to a 20N downward force, which is negligible for ordinary mechanical clamping. For the packaging based on a solder, no external force is applied.

It can be seen from FIG. 3 that the thermo-mechanical stress on the SiC chip in the packaging based on liquid metal is significantly lower than that of the packaging based on a solder. This improves reliability since the internal high stress chip may cause device cracking. The stress of the packaging based on liquid metal is mainly distributed near a source electrode soldering pad soldered to the flexible printed circuit board. Besides, the flexible printed circuit board is thin and the Young modulus of the polyimide is low, such that the small solder connection between the chip and the flexible printed circuit board does not cause high stress. In contrast, for the packaging based on solder, the top and bottom surfaces of the chip are respectively soldered to the flexible printed circuit board and the cermet substrate. The rigid connection to the thick copper of the cermet substrate produces a very high stress. Therefore, the average von mises stress of the chip in the solder packaging is 2.25 times higher than the design based on liquid metal.

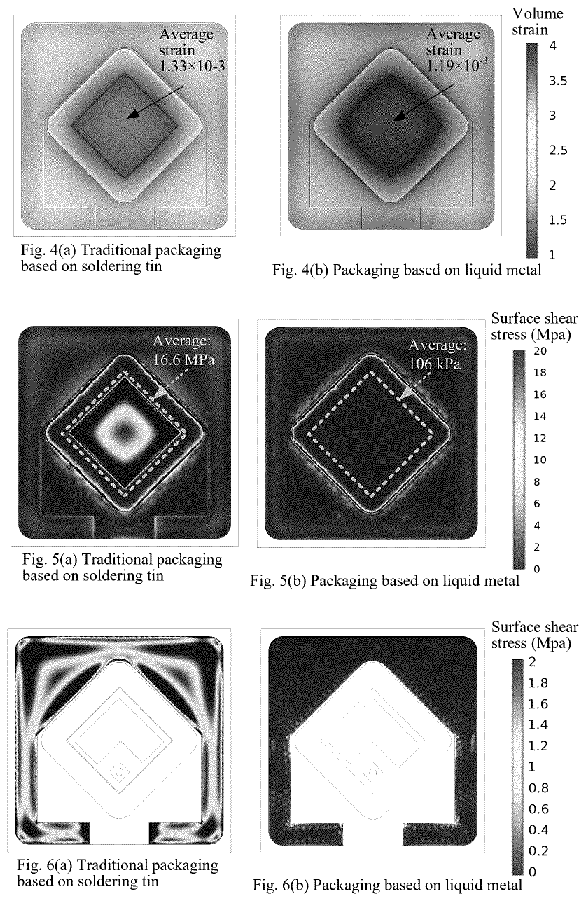

As shown in FIG. 4, since the CTE of the chip is lower than that of the cermet substrate, the thermal strain is also low. For packaging based on liquid metal, the difference in the thermal strain between the cermet substrate and the chip is not a problem since the cermet substrate is decoupled with the floating chip structure by the liquid metal. Therefore, compared with the packaging based on a solder, the strain of the chip packaged by the liquid metal is low, while the strain of the cermet substrate is high. For the packaging based on a solder, the rigid connection enables the SiC chip to be subjected to a tension and the cermet substrate is subjected to compression, thereby creating significant shear stress between the chip, solder and cermet substrate.

The shear stress of the cermet substrate is shown in FIG. 5. For the packaging based on a solder, the average shear stress in the groove reaches 16.6 MPa. However, for the packaging based on liquid metal, the average shear stress in the groove is only 106 kPa, reduced by 99.4%. The large balance of the shear stress is due to decoupling of the strain of the chip and the cermet substrate by the connection with the fluid liquid metal. Notably, the shear stress outside the cavity is also reduced: in FIG. 5(a), the high shear stress between the flexible printed circuit board and the cermet substrate is caused by the rigid connection by a solder. The stress is almost eliminated by connecting the flexible printed circuit board and the cermet substrate by the fluid liquid metal as shown in FIG. 5(b).

FIG. 6 also compares the shear stress of the bottom copper layer of the flexible printed circuit board. The average surface shear stress of the packaging based on a solder reaches 3.95 MPa, whereas the average surface shear stress of the packaging based on liquid metal is only 0.74 MPa. This is because the rigid connection of the packaging based on solder becomes the fluid connection in the packaging based on liquid metal. Besides, the force on the copper surface becomes a friction force, such that the mismatched coefficient of thermal expansion (CTE) results in a significant reduction in the shear stress. The lower shear force on the copper layer may reduce the possibility of layering of the flexible printed circuit board to improve reliability.

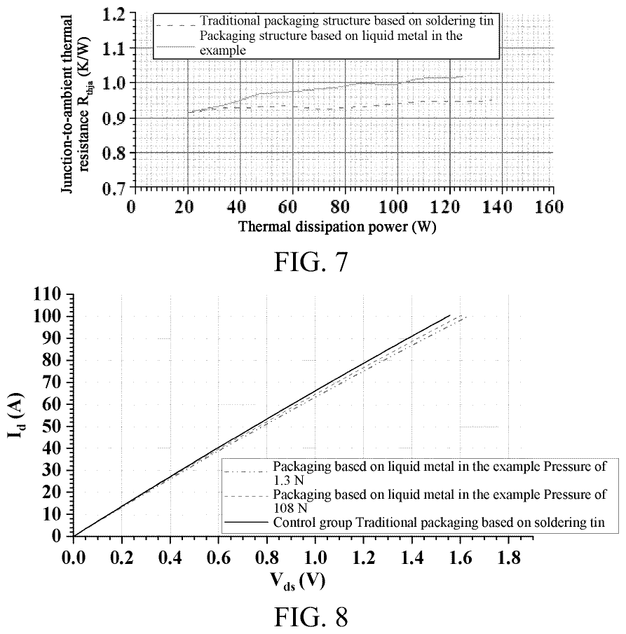

The thermal resistance results at different power consumptions are shown in FIG. 7. It can be seen that the thermal resistance of the packaging based on liquid metal increases slightly with increasing power consumption, from 0.92 K/W to 1.04 K/W. This is because at high power losses, the high temperature increases the scattering of free electrons inside the liquid metal, thereby reducing its thermal conductivity. However, even so, the average thermal resistance of the packaging based on liquid metal is only 5% higher than that of the packaging based on a solder.

By replacing the water cooling plate with a pressure sensor, the downward force (clamping force) applied to the packaging can be measured. The properties of the packaging based on liquid metal have been tested under different clamping forces. The results of a B1505A curve tracker are shown in FIG. 8. When the force applied to the flexible printed circuit board exceeds 4.3 N, its effect on the on-resistance is negligible. This means that packaging design based on liquid metal requires only a very low clamping force to achieve good electrical contact between the flexible printed circuit board, chip and cermet substrate. In practice, this pressure is lower than the pressure required to connect a power module to a radiator. The on-resistance R_{dson} of the packaging based on a solder and the packaging based on liquid metal is 15.53 mΩ and 15.98 mΩ respectively, which are very close.

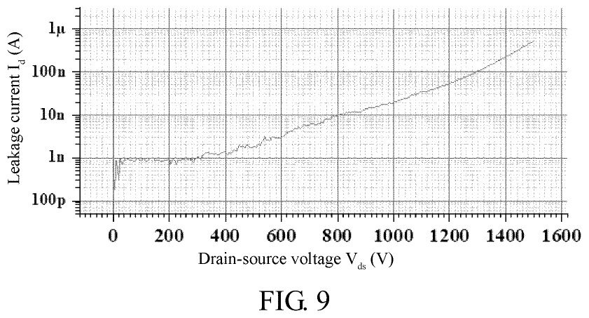

In order to verify the provided voltage blocking capability of the packaging based on liquid metal, the leakage current is measured and the results are shown in FIG. 9. When the voltage exceeds 1.5 kV or the leakage current exceeds 1 μA, the measurement is stopped. The packaging based on liquid metal has the leakage current of 640 nA at 1.5 kV. This indicates that the packaging based on liquid metal does not show partial discharge and breakdown even at the voltage beyond the rated voltage of SiC MOSFET. This indicates that the packaging based on gallium indium silver alloy liquid metal does not affect the voltage blocking capability of the device.

In other embodiments, the flexible upper printed circuit board can also be replaced by a cermet substrate, a metal button or a bonding wire. The cermet substrate can also be replaced by a common printed circuit board, a flexible printed circuit board, a metal copper plate or a metal copper frame.

The above examples only illustratively describe the principles and efficacie of the present invention and a part of used examples, but are not used to limit the present invention. It should be pointed out that a person of ordinary skill in the art may further make several transformations and improvements without departing from the ideas of the present invention, but all the transformations and improvements fall within the protection scope of the present invention.

1. A power module packaging structure based on liquid metal, comprising an upper printed circuit board or an upper cermet substrate, a power semiconductor chip and a lower cermet substrate, wherein a lower surface copper layer of the upper printed circuit board is connected with the power semiconductor chip through a soldering layer, a groove is formed in an upper copper layer of the lower cermet substrate through etching, the surface of the upper copper layer of the lower cermet substrate is subjected to silver plating, liquid metal is filled in the groove, and the power semiconductor chip is embedded into the liquid metal in the groove so as to realize electrical connection between the upper surface of the lower cermet substrate and the lower surface of the power semiconductor chip;
an insulating sealing ring is arranged on the upper printed circuit board around the power semiconductor chip to prevent the liquid metal from entering between the power semiconductor chip and the upper printed circuit board to cause short circuit; the liquid metal absorbs the lower cermet substrate and the upper printed circuit board together through surface tension; and
a grid electrode and a source electrode of the lower surface copper layer of the upper printed circuit board are connected with a grid electrode and a source electrode of the power semiconductor chip through the soldering layer, and a drain electrode copper layer on the lower surface of the power semiconductor chip is connected with the upper surface copper layer of the cermet substrate through the liquid metal; the lower surface copper layer of the upper printed circuit board is connected to the corresponding copper layer on the flexible upper surface through a through hole so as to realize electrical connection between the copper layers of the upper surface and the lower surface; and an upper surface copper layer of the upper printed circuit board is used as a power terminal of the packaging structure.

2. The power module packaging structure based on liquid metal according to claim 1, wherein the insulating sealing ring is made of epoxy resin, silicon rubber, polyamide, polyimide or resin.

3. The power module packaging structure based on liquid metal according to claim 1, wherein the power semiconductor chip is a silicon carbide power semiconductor chip or a gallium nitride power semiconductor chip or a silicon power semiconductor chip or a gallium oxide power semiconductor chip or a diamond power semiconductor chip.

4. The power module packaging structure based on liquid metal according to claim 1, wherein the liquid metal is gallium indium silver alloy or gallium indium tin alloy.

5. The power module packaging structure based on liquid metal according to claim 1, wherein the lower cermet substrate is of a copper-ceramic-copper three-layer structure.

6. The power module packaging structure based on liquid metal according to claim 1, wherein the upper printed circuit board is a common printed circuit board or a flexible printed circuit board.

7. The power module packaging structure based on liquid metal according to claim 2, wherein the upper printed circuit board is a common printed circuit board or a flexible printed circuit board.

8. The power module packaging structure based on liquid metal according to claim 3, wherein the upper printed circuit board is a common printed circuit board or a flexible printed circuit board.

9. The power module packaging structure based on liquid metal according to claim 4, wherein the upper printed circuit board is a common printed circuit board or a flexible printed circuit board.

10. The power module packaging structure based on liquid metal according to claim 5, wherein the upper printed circuit board is a common printed circuit board or a flexible printed circuit board.
